(19) United States
(12) Patent Application Publication
(10) Pub. No.: US 2024/0237309 A1
(43) Pub. Date: Jul. 11, 2024

(54) AUTOMOTIVE LIQUID-COOLING COOLER STRUCTURE

(71) Applicant: AMULAIRE THERMAL TECHNOLOGY, INC., New Taipei City (TW)

(72) Inventors: Kuo-Wei LEE, New Taipei City (TW); Tze-Yang YEH, New Taipei City (TW)

(21) Appl. No.: 18/152,114

(22) Filed: Jan. 9, 2023

(51) Int. Cl. H05K 7/20; B23K 20/12

(52) U.S. Cl. CPC H05K 7/20872; B23K 20/122; B23K 2101/14

(57) ABSTRACT

An automotive liquid-cooling cooler structure is provided, which includes: a liquid-cooling cooler body, an outer frame, and a reserved structure. The liquid-cooling cooler body is located in a frame opening of the outer frame, the reserved structure is located at a gap between the liquid-cooling cooler body and the outer frame, and the reserved structure is configured for joining the liquid-cooling cooler body to the outer frame by friction stir welding.

### FIELD OF THE DISCLOSURE

The present disclosure relates to a cooler structure, and more particularly to an automotive liquid-cooling cooler structure.

### BACKGROUND OF THE DISCLOSURE

Coolers are widely used in various products. Since an operating speed of an automotive electronic component module (e.g., an advanced driver-assistance system (ADAS) module) is becoming faster and faster, water/liquid-cooling coolers are usually adopted due to having advantages of quietness and a stable cooling performance compared to air-cooling coolers. Further, an automotive liquid-cooling cooler generally needs an intermediate component for forming a connection with the ADAS module. However, the automotive liquid-cooling cooler and the intermediate component often have a poor joining property in an environment of high temperature and high humidity. As such, the joining reliability between the automotive liquid-cooling cooler and the intermediate component is not high, and a large amount of manufacturing time is required to ensure the joining reliability.

### SUMMARY OF THE DISCLOSURE

In response to the above-referenced technical inadequacies, the present disclosure provides an automotive liquid-cooling cooler structure.

In one aspect, the present disclosure provides an automotive liquid-cooling cooler structure, which includes: a liquid-cooling cooler body, an outer frame, and a reserved structure. The liquid-cooling cooler body is located in a frame opening of the outer frame, the reserved structure is located at a gap between the liquid-cooling cooler body and the outer frame, and the reserved structure is configured for joining the liquid-cooling cooler body to the outer frame by friction stir welding.

In one exemplary embodiment, the liquid-cooling cooler body includes a metal housing, a plurality of liquid connectors located outside the metal housing, and a plurality of fins located inside the metal housing.

In one exemplary embodiment, the metal housing includes a first cover and a second cover, the first cover and the second cover are joined to form a cavity, and the plurality of fins are arranged in the cavity. One or more protrusions are protrudingly formed on at least one of the first cover and the second cover, and the one or more protrusions are configured to be in contact with one or more heating elements in a corresponding manner.

In one exemplary embodiment, each of the first cover and the second cover is one of a forged piece, a cast piece, a die-cast piece, and a metal injection-molded piece, and each of the first cover and the second cover is made from one of copper, aluminum, a copper alloy, and an aluminum alloy.

In one exemplary embodiment, the outer frame is one of a cast piece, a die-cast piece, an extruded piece, a machined piece, and a metal assembly, and the outer frame is made from one of copper, aluminum, a copper alloy, and an aluminum alloy.

In one exemplary embodiment, the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body. The at least one first reserved planar structure and the at least one second reserved planar structure correspondingly form a lap joint, so that a solid-state welded portion is formed between the at least one first reserved planar structure and the at least one second reserved planar structure by friction stir welding.

In one exemplary embodiment, the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body. The at least one first reserved planar structure and the at least one second reserved planar structure correspondingly form an abutting joint, so that a solid-state welded portion is formed between the at least one first reserved planar structure and the at least one second reserved planar structure by friction stir welding.

In one exemplary embodiment, the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body. The at least one first reserved planar structure and the at least one second reserved planar structure correspondingly form a T-shaped connection, so that a solid-state welded portion is formed between the at least one first reserved planar structure and the at least one second reserved planar structure by friction stir welding.

In one exemplary embodiment, the reserved structure includes at least one first reserved arc-shaped structure formed by the liquid-cooling cooler body extending toward an inner periphery of the outer frame and at least one second reserved arc-shaped structure formed by the inner periphery of the outer frame extending toward the liquid-cooling cooler body. The at least one first reserved arc-shaped structure and the at least one second reserved arc-shaped structure correspondingly form a lap joint, so that a solid-state welded portion is formed between the at least one first reserved arc-shaped structure and the at least one second reserved arc-shaped structure by friction stir welding.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic partially exploded view of a first embodiment of the present disclosure;

FIG. 2 is a schematic partially assembled view of the first embodiment of the present disclosure;

FIG. 3 is a schematic assembled perspective view of the first embodiment of the present disclosure;

FIG. 4 is a schematic cross-sectional structural view taken along line IV-IV of FIG. 3;

FIG. 5 is a schematic view showing a friction stir welding process being performed on the first embodiment of the present disclosure;

FIG. 6 is a schematic view showing the first embodiment of the present disclosure after the friction stir welding process;

FIG. 7 is a schematic view showing the friction stir welding process being performed on a second embodiment of the present disclosure;

FIG. 8 is a schematic view showing the second embodiment of the present disclosure after the friction stir welding process;

FIG. 9 is a schematic partially assembled view of a third embodiment of the present disclosure; and

FIG. 10 is a schematic partially assembled view of a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

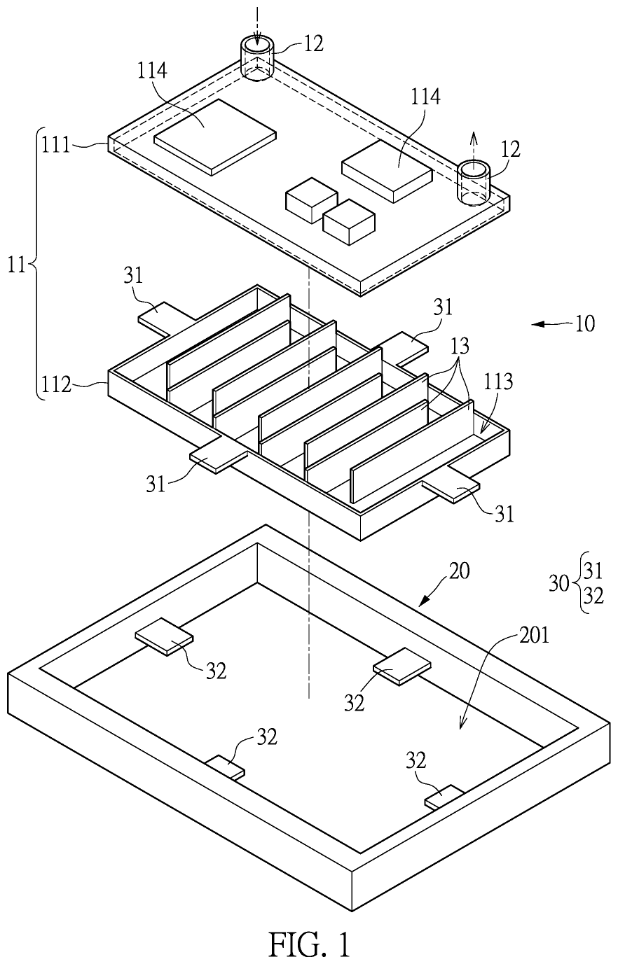

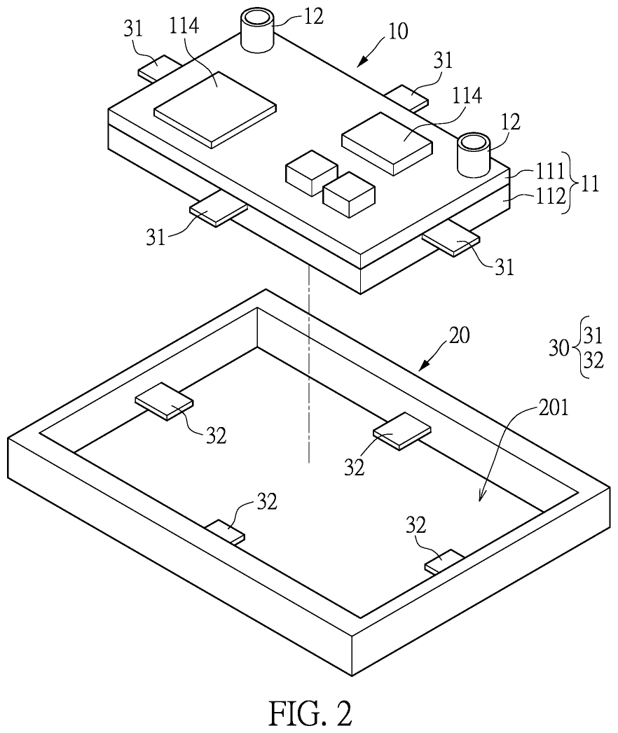

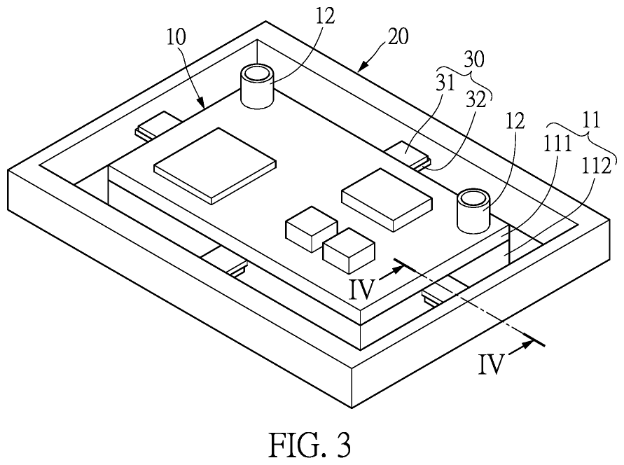

Reference is made to FIG. 1 to FIG. 6, which show one embodiment of the present disclosure. The present embodiment provides an automotive liquid-cooling cooler structure. As shown in the drawings, the automotive liquid-cooling cooler structure provided in the present embodiment essentially includes a liquid-cooling cooler body 10, an outer frame 20, and a reserved structure 30.

The liquid-cooling cooler body 10 includes a metal housing 11, a plurality of liquid connectors 12 located outside the metal housing 11, and a plurality of fins 13 located inside the metal housing 11.

Moreover, the metal housing 11 includes a first cover 111 and a second cover 112 that are joined to one another, and the liquid connectors 12 are disposed on the first cover 111 or the second cover 112. That is, the liquid connectors 12 can all be disposed on one of the first cover 111 and the second cover 112, or can be disposed on both of the first cover 111 and the second cover 112, and the present disclosure is not limited in this regard. In the present embodiment, a quantity of the liquid connectors 12 is two, and the two liquid connectors 12 are both disposed on the first cover 111. One of the liquid connectors 12 can be used as a liquid inlet connector, and another one of the liquid connectors 12 can be used a liquid outlet connector. Further, a cavity 113 formed between the first cover 111 and the second cover 112 is in spatial communication with the two liquid connectors 12, and the fins 13 are arranged in the cavity 113 for formation of a winding liquid passageway. However, an arrangement configuration of the fins 13 is not limited thereto.

Each of the first cover 111 and the second cover 112 can be a forged piece, a cast piece, a die-cast piece, or a metal injection-molded piece, and each of the first cover 111 and the second cover 112 can be made from copper, aluminum, a copper alloy, or an aluminum alloy. Preferably, each of the first cover 111 and the second cover 112 of the present embodiment is a stamped piece made from the aluminum alloy, and advantages thereof include having a high strength and being corrosion-resistant. Further, the liquid connector 12 can be a liquid connector of aluminum alloy, and the fin 13 can be an aluminum fin. The first cover 111, the second cover 112, the liquid connectors 12, and the fins 13 can be joined by brazing or soldering beforehand.

The outer frame 20 can be an integral or a combined metal piece. The outer frame 20 can be a cast piece, a die-cast piece, an extruded piece, a machined piece, or a metal assembly, and the outer frame 20 is made from copper, aluminum, a copper alloy, or an aluminum alloy. Preferably, the outer frame 20 is a die-cast piece of aluminum alloy.

The liquid-cooling cooler body 10 is located in a frame opening 201 of the outer frame 20, such that a gap is formed between the liquid-cooling cooler body 10 and the outer frame 20. The reserved structure 30 is located at the gap between the liquid-cooling cooler body 10 and the outer frame 20. Moreover, the reserved structure 30 is configured for joining the liquid-cooling cooler body 10 to the outer frame 20 by friction stir welding (FSW). In this way, purposes of enhancing the joining reliability and saving the manufacturing time can be achieved.

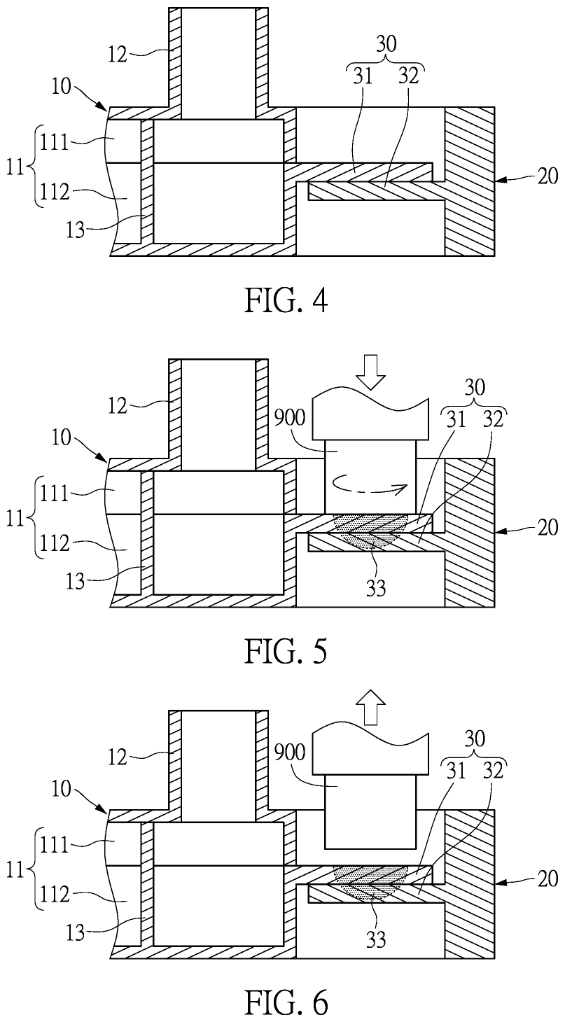

The reserved structure 30 can be pre-formed on the liquid-cooling cooler body 10, the outer frame 20, or both of the liquid-cooling cooler body 10 and the outer frame 20. More specifically, the reserved structure 30 can include a plurality of first reserved planar structures 31 formed by the metal housing 11 of the liquid-cooling cooler body 10 extending toward an inner periphery of the outer frame 20 and a plurality of second reserved planar structures 32 formed by the inner periphery of the outer frame 20 extending toward the metal housing 11 of the liquid-cooling cooler body 10. In addition, the first reserved planar structure 31 and the second reserved planar structure 32 correspondingly form a lap joint (as shown in FIG. 4). Accordingly, a friction stir tool 900 may enter the gap between the metal housing 11 of the liquid-cooling cooler body 10 and the inner periphery of the outer frame 20 for performing friction stir welding on the first reserved planar structure 31 or the second reserved planar structure 32, so that a specific solid-state welded portion 33 (as shown in FIG. 5 and FIG. 6) is formed between the first reserved planar structure 31 and the second reserved planar structure 32 by friction stir welding. Said solid-state welded portion 33 can be used as a joining point of the liquid-cooling cooler body 10 and the outer frame 20, so as to achieve the purposes of enhancing the joining reliability and saving the manufacturing time.

In the present embodiment, the second cover 112 of the metal housing 11 has four outer wall surfaces, and the inner periphery of the outer frame 20 has four inner frame surfaces. A quantity of the first reserved planar structures 31 formed by the four outer wall surfaces of the second cover 112 of the metal housing 11 horizontally extending toward the four inner frame surfaces of the inner periphery of the outer frame 20 is four, and a quantity of the second reserved planar structures 32 formed by the four inner frame surfaces of the inner periphery of the outer frame 20 horizontally extending toward the four outer wall surfaces of the second cover 112 of the metal housing 11 is four. Further, a friction stir welding process can be performed on all of the first reserved planar structures 31 and the second reserved planar structures 32, or can be partially performed on selected ones of the first reserved planar structures 31 and the second reserved planar structures 32, so as to save the manufacturing time.

In detail, the first reserved planar structure 31 and the second reserved planar structure 32 each have a width that ranges between 2 mm and 40 mm (preferably between 5 mm and 20 mm), and each have a thickness that ranges between 0.1 mm and 10 mm (preferably between 0.5 mm and 4.5 mm).

In the present embodiment, no limitation is imposed on the size (length, width, and height) of the outer frame 20, which may vary according to practical requirements. Specifically, the outer frame 20 can correspond in shape to a circuit board of an automotive electronic component module (e.g., a circuit board of an ADAS module), so as to attach the circuit board of the automotive electronic component module to the outer frame 20. One or more protrusions 114 are protrudingly formed on the first cover 111 or the second cover 112 of the metal housing 11, and the one or more protrusions 114 correspond in position and size to one or more heating elements (e.g., power chips) on the circuit board of the automotive electronic component module, so that the one or more heating elements on the circuit board of the automotive electronic component module can be in contact with the one or more protrusions 114 in a corresponding manner. In addition, the one or more protrusions 114 can be integrally formed with the first cover 111 or the second cover 112 by stamping, and can also be joined with the first cover 111 or the second cover 112 by brazing.

### Second Embodiment

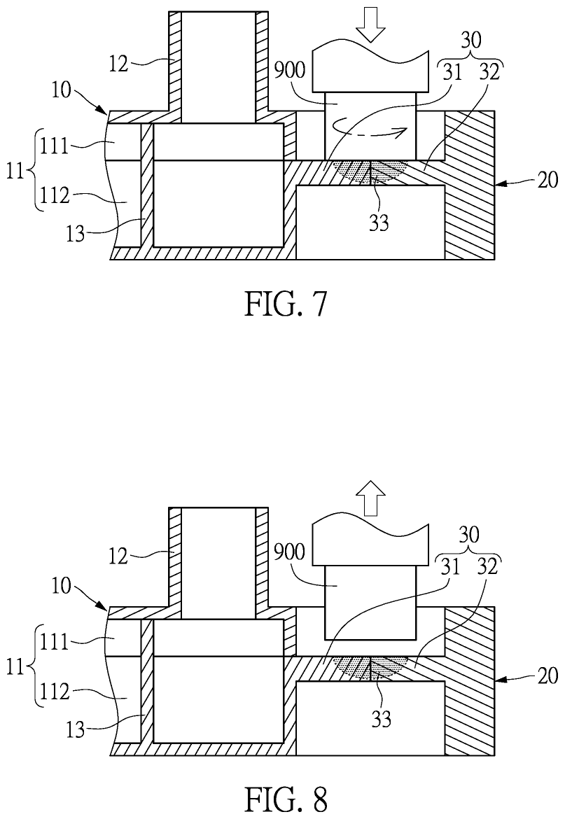

Reference is made to FIG. 7 and FIG. 8, which show a second embodiment of the present disclosure. The present embodiment is substantially the same as the first embodiment, and their differences are illustrated below.

In the present embodiment, the first reserved planar structure 31 and the second reserved planar structure 32 of the reserved structure 30 correspondingly form an abutting joint. Further, the friction stir tool 900 may enter the gap between the metal housing 11 of the liquid-cooling cooler body 10 and the inner periphery of the outer frame 20 for performing friction stir welding on an abutting joint part of the first reserved planar structure 31 and the second reserved planar structure 32, so that the specific solid-state welded portion 33 is formed between the first reserved planar structure 31 and the second reserved planar structure 32 by friction stir welding.

### Third Embodiment

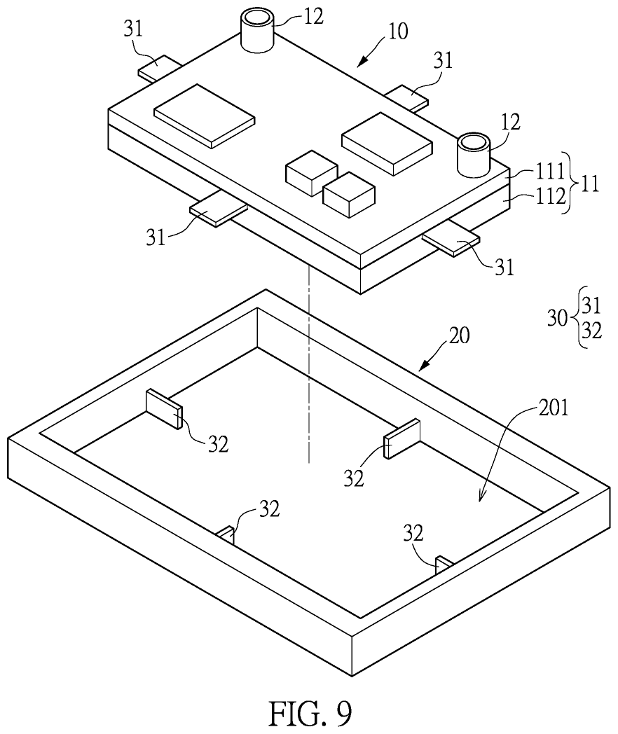

Reference is made to FIG. 9, which shows a third embodiment of the present disclosure. The present embodiment is substantially the same as the first embodiment, and their differences are illustrated below.

In the present embodiment, the first reserved planar structure 31 and the second reserved planar structure 32 of the reserved structure 30 are perpendicular to each other. By arranging the two planar structures to be perpendicular to each other, the first reserved planar structure 31 and the second reserved planar structure 32 can correspondingly form a T-shaped connection. Further, the friction stir tool 900 may enter the gap between the metal housing 11 of the liquid-cooling cooler body 10 and the inner periphery of the outer frame 20 for performing friction stir welding on the first reserved planar structure 31 or the second reserved planar structure 32, so that the specific solid-state welded portion 33 is formed between the first reserved planar structure 31 and the second reserved planar structure 32 by friction stir welding.

### Fourth Embodiment

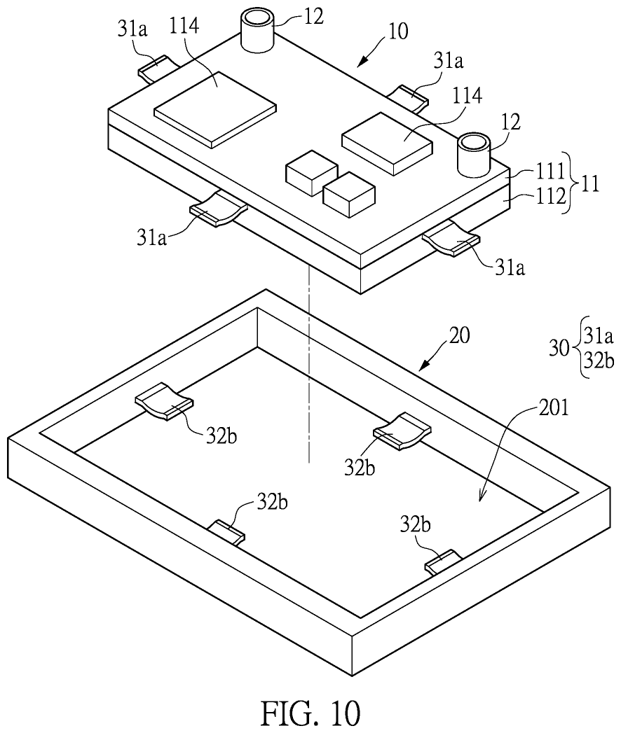

Reference is made to FIG. 10, which shows a fourth embodiment of the present disclosure. The present embodiment is substantially the same as the first embodiment, and their differences are illustrated below.

In the present embodiment, the reserved structure 30 can include a plurality of first reserved arc-shaped structures 31a formed by the metal housing 11 of the liquid-cooling cooler body 10 extending toward the inner periphery of the outer frame 20 and a plurality of second reserved arc-shaped structures 32b formed by the inner periphery of the outer frame 20 extending toward the metal housing 11 of the liquid-cooling cooler body 10, and the first reserved arc-shaped structure 31a and the second reserved arc-shaped structure 32b can correspondingly form the lap joint in an improved manner. Further, the friction stir tool 900 may enter the gap between the metal housing 11 of the liquid-cooling cooler body 10 and the inner periphery of the outer frame 20 for performing friction stir welding on the first reserved arc-shaped structure 31a or the second reserved arc-shaped structure 32b, so that the specific solid-state welded portion 33 is formed between the first reserved arc-shaped structure 31a and the second reserved arc-shaped structure 32b by friction stir welding.

### Beneficial Effects of the Embodiments

In conclusion, in the automotive liquid-cooling cooler structure provided by the present disclosure, by virtue of “a liquid-cooling cooler body,” “an outer frame,” “a reserve structure,” “the liquid-cooling cooler body being located in a frame opening of the outer frame,” “the reserved structure being located at a gap between the liquid-cooling cooler body and the outer frame,” and “the reserved structure being configured for joining the liquid-cooling cooler body to the outer frame by friction stir welding,” the purposes of enhancing the joining reliability and saving the manufacturing time can be effectively achieved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An automotive liquid-cooling cooler structure, comprising: a liquid-cooling cooler body, an outer frame, and a reserved structure; wherein the liquid-cooling cooler body is located in a frame opening of the outer frame, the reserved structure is located at a gap between the liquid-cooling cooler body and the outer frame, and the reserved structure is configured for joining the liquid-cooling cooler body to the outer frame by friction stir welding.

2. The automotive liquid-cooling cooler structure according to claim 1, wherein the liquid-cooling cooler body includes a metal housing, a plurality of liquid connectors located outside the metal housing, and a plurality of fins located inside the metal housing.

3. The automotive liquid-cooling cooler structure according to claim 2, wherein the metal housing includes a first cover and a second cover, the first cover and the second cover are joined to form a cavity, and the plurality of fins are arranged in the cavity; wherein one or more protrusions are protrudingly formed on at least one of the first cover and the second cover, and the one or more protrusions are configured to be in contact with one or more heating elements in a corresponding manner.

4. The automotive liquid-cooling cooler structure according to claim 3, wherein each of the first cover and the second cover is one of a forged piece, a cast piece, a die-cast piece, and a metal injection-molded piece, and each of the first cover and the second cover is made from one of copper, aluminum, a copper alloy, and an aluminum alloy.

5. The automotive liquid-cooling cooler structure according to claim 4, wherein the outer frame is one of a cast piece, a die-cast piece, an extruded piece, a machined piece, and a metal assembly, and the outer frame is made from one of copper, aluminum, a copper alloy, and an aluminum alloy.

6. The automotive liquid-cooling cooler structure according to claim 1, wherein the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body; wherein the at least one first reserved planar structure and the at least one second reserved planar structure correspondingly form a lap joint, so that a solid-state welded portion is formed between the at least one first reserved planar structure and the at least one second reserved planar structure by friction stir welding.

7. The automotive liquid-cooling cooler structure according to claim 1, wherein the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body; wherein the at least one first reserved planar structure and the at least one second reserved planar structure correspondingly form an abutting joint, so that a solid-state welded portion is formed between the at least one first reserved planar structure and the at least one second reserved planar structure by friction stir welding.

8. The automotive liquid-cooling cooler structure according to claim 1, wherein the reserved structure includes at least one first reserved planar structure formed by the liquid-cooling cooler body extending toward an inner periphery of the outer frame and at least one second reserved planar structure formed by the inner periphery of the outer frame extending toward the liquid-cooling cooler body; wherein the at least one first reserved planar structure and the at least one second reserved planar structure correspondingly form a T-shaped connection, so that a solid-state welded portion is formed between the at least one first reserved planar structure and the at least one second reserved planar structure by friction stir welding.

9. The automotive liquid-cooling cooler structure according to claim 1, wherein the reserved structure includes at least one first reserved arc-shaped structure formed by the liquid-cooling cooler body extending toward an inner periphery of the outer frame and at least one second reserved arc-shaped structure formed by the inner periphery of the outer frame extending toward the liquid-cooling cooler body; wherein the at least one first reserved arc-shaped structure and the at least one second reserved arc-shaped structure correspondingly form a lap joint, so that a solid-state welded portion is formed between the at least one first reserved arc-shaped structure and the at least one second reserved arc-shaped structure by friction stir welding.
